(19) United States
(12) Patent Application Publication
(10) Pub. No.: US 2005/0199900 A1
(43) Pub. Date: Sep. 15, 2005

(54) Light-emitting device with high heat-dissipating efficiency

(76) Inventors: Ming-Der Lin, Hsinchu (TW); San Bao Lin, Jungli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/019,171

(22) Filed: Dec. 23, 2004

(30) Foreign Application Priority Data
Mar. 12, 2004 (TW) 093106604

(51) Int. Cl. H01L 29/22

(52) U.S. Cl. 257/99

(57) ABSTRACT

A light-emitting device with high heat-dissipating efficiency, includes a ceramic substrate having at least one pair of power-supply circuits mounted at a specific location of the substrate, a light-emitting die fixedly mounted on the ceramic substrate by flip-chip mounting, wherein the two electrodes of the light-emitting die are electrically connected to a corresponding power-supply circuit, respectively, and an optical reflector which is adjacently mounted in the periphery of the light-emitting die and made up of a metallic material or a material with a high coefficient of thermal conductivity for increasing the heat-dissipating area and providing a light-guiding mechanism.

### FIELD OF THE INVENTION

The present invention is related to a light-emitting device, and more particularly to a light-emitting device with high heat-dissipating efficiency, including an optical reflector incorporating the capabilities of light-guiding and heat-dissipating for increasing the heat-dissipating area and providing the light-guiding capability.

### BACKGROUND OF THE INVENTION

As is well known in the prior art, a light-emitting diode has been widely employed in computer peripherals, communication products, and other electronic device because of its light weight, low power consumption, and prolonged longevity.

For a high-power light-emitting diode, especially a light-emitting diode serving for the purpose of illumination, the operating current of the light-emitting diode has to be increased or the dimension of the light-emitting die has to be upgraded in order to provide a better illumination.

However, with the increase of the operating current of the light-emitting diode, the light-emitting die is bound to generate more heat energy, and thus the operating temperature of the light-emitting die is raised as well. Moreover, the higher operating temperature the light-emitting die has, the lower light-emitting efficiency the light-emitting diode provides. What is worse, the light-emitting die may be permanently damaged. Hence, how to dissipate the heat energy generated by the light-emitting diode to the outside in good time so as to maintain an appropriate operating temperature of the light-emitting diode and enhance the light-emitting efficiency of the light-emitting diode for saving energy is a major task in the research and development of a light-emitting diode.

Referring to FIG. 1 and FIG. 2, a top view and a side view of a conventional light-emitting diode with an improved heat-dissipating effect are respectively illustrated. As shown, the light-emitting diode 10 at least includes a pair of metal plates 12,14, a light-emitting die fixedly mounted on the metal plate 12, and a substrate 11 encapsulating a portion of the metal plates 12 and 14. The substrate 11 includes a central plane 113 which is sunken in the center of the substrate 11, and wherein the central plane 113 includes a slope 115 formed in its periphery. The metal plate 12 is configured to protrude from the substrate 11 via the central plane 113 and radiate outwardly to form a plurality of metal strips 121,123,125. The metal plate 14 is configured to protrude from the substrate 11 via the central plane 113 and extends outwardly to form a metal strip 141. The metal strips 121 and 123 are configured to extend along a side surface 112 of the substrate 11 to one side of the bottom surface 117, and the metal strips 125 and 141 are configured to extend along a side surface 114 being opposite to the side surface 113 to the other side of the bottom surface 117. The two electrodes of the light-emitting die 13 are electrically connected to the metal plates 12 and 14, respectively, and an epoxy resin 15 is filled in the gap above the light-emitting die 13. The metal strips 121,123,125 serve as a first external electrode, and the metal strip 141 serves as a second external electrode. An operating power source is electrically conducted via the first external electrode and the second external electrode to allow the light-emitting diode 10 to project a light source.

The substrate 11 of the light-emitting diode 10 is generally made up by a pressure-molding or an injection-molding method, and the manufacturing material of the substrate 11 is selected as a thermal-molding plastic material. Because the plastic material has a low coefficient of thermal conductivity, the heat energy of the light-emitting die 13 is conducted via the metal plate 12 with a large coefficient of thermal conductivity, and dissipated to the outside of the light-emitting diode 10 via the metal strips 121,123,125 which are exposed to the outside of the substrate 11. However, the metal strips 121,123,125 and the metal strip 141 also serve as the first external electrode and the second external electrode for connecting to an external power source, respectively. When the temperature of the metal strips 121,123,125 and the metal strip 141 is rising, the current of the light-emitting diode 10 may become unstable, which would even cause electric leakage or jeopardize the circuit board (not shown) to which the light-emitting diode is coupled as a result of its rising temperature.

### SUMMARY OF THE INVENTION

Thus, it is a keynote of the present invention to devise a novel light-emitting device with high heat-dissipating efficiency, which is capable of ensuring the safety in operation and reducing the manufacturing cost.

A primary object of the present invention is to provide a light-emitting device with high heat-dissipating efficiency which enables an optical reflector that is used for guiding the light source to dissipate the heat energy generated by the light-emitting device, without the need of incorporating an additional heat sink or other heat-dissipating device into the light-emitting device.

A secondary object of the present invention is to provide a light-emitting device with high heat-dissipating efficiency which dissipates the heat energy generated thereby to the outside via an optical reflector, such that the temperature of the power-supply circuit of the light-emitting device is prevented from rising, and the negative effect, such as the electric leakage or the instability of the current of the light-emitting device, is avoided.

Another object of the present invention is to provide a light-emitting device with high heat-dissipating efficiency, which can prevent the temperature of the encapsulated light-emitting die from rising through the improvement of the heat-dissipating efficiency, such that the light-emitting die is operating under a high-luminance state in order to save energy and achieve a green illumination.

To attain the foregoing objects, the present invention provides a light-emitting device with high-dissipating efficiency, comprising: a substrate having at least one pair of power-supply circuits mounted thereon; at least one light-emitting die fixedly mounted on the top surface of the substrate, wherein two electrodes of the light-emitting die are electrically connected to a corresponding power-supply circuit, respectively; and an optical reflector provided with heat-dissipating capability which is fixedly mounted on the top surface of the substrate and adjacently surrounds the light-emitting die for dissipating the heat energy generated by the light-emitting die to the outside of the light-emitting device.

Now the foregoing and other features and advantages of the present invention will be best understood through the following descriptions with reference to the accompanying drawings, wherein:

### BRIEF DESCRIPTION OF THE DRAWINGS

FIG. 1 is a top view of a light-emitting diode with improved heat-dissipating efficiency according to the prior art;

FIG. 2 is a side view of the light-emitting device of FIG. 1;

FIG. 3 is a side view of a light-emitting device according to a preferred embodiment of the present invention;

FIG. 4 is a top view of the light-emitting device of FIG. 3;

FIG. 5 is a side view of a light-emitting device according to another embodiment of the present invention; and

FIG. 6 is a top view of the light-emitting device of FIG. 5.

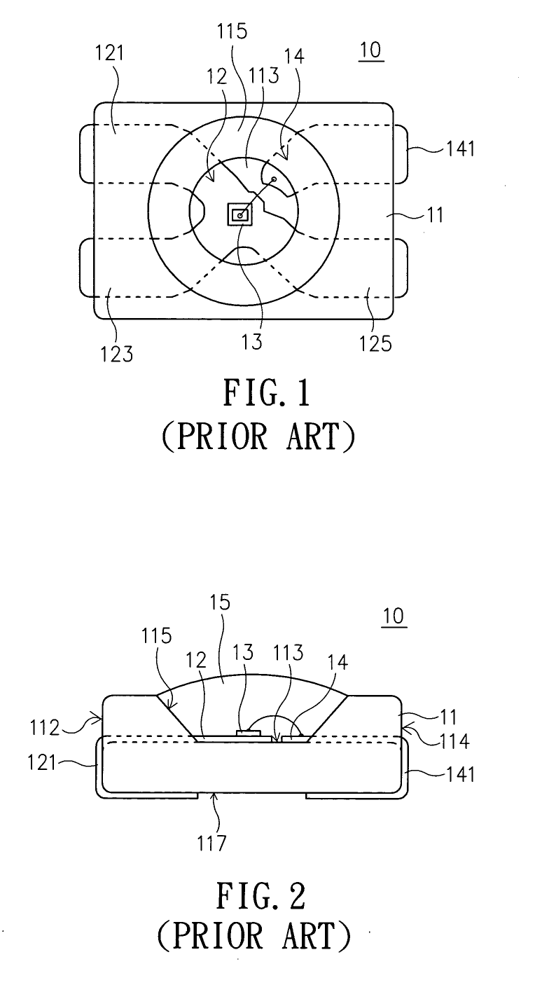

### DETAILED DESCRIPTION OF THE PREFERRED EMBODIMENT

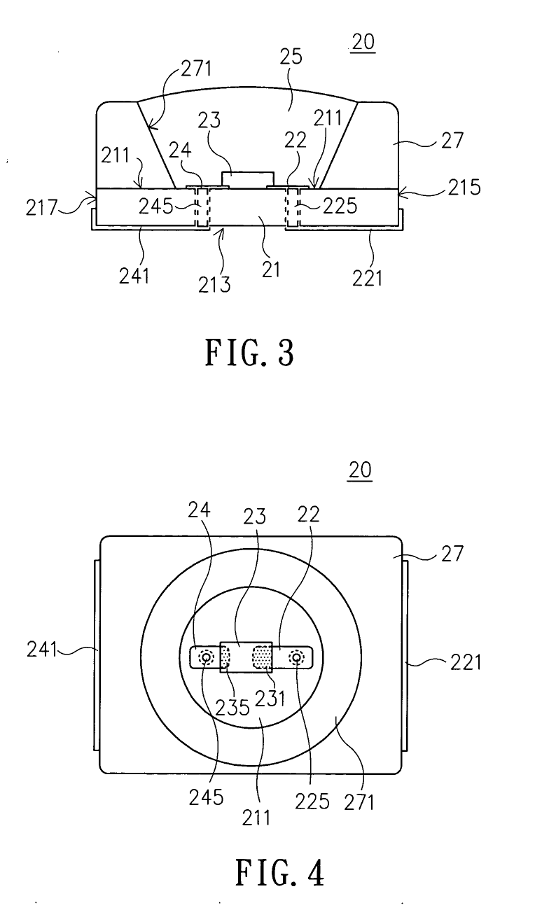

Referring to FIG. 3 and FIG. 4, a side view and a top-view of the light-emitting device according to a preferred embodiment of the present invention are respectively illustrated. As shown, a light-emitting device 20 with high heat-dissipating efficiency according to the present invention includes a substrate 21, at least one light-emitting die 23 fixedly mounted on the top surface 211 of the substrate 21, and an optical reflector 37 adjacently surrounding the light-emitting die 21 and fixedly mounted on the substrate 21.

In addition, a pair of power-supply circuits 22,24 are directly mounted on the substrate 21 and protrude from the substrate 21 via perforations 225 and 245, and further extends to the bottom surface 213 and the side surfaces 215,217 to form external electrodes 221,241. The light-emitting die 23 is fixedly mounted on the top surface 211 of the substrate 21 by the flip-chip mounting, and the two electrodes 231,235 are electrically connected to a corresponding power-supply circuit 22,24, respectively. The optical reflector 27 is mounted around the periphery of the light-emitting die 23, which is located on the top surface 211 of the substrate 21, and is adhered to the substrate 21.

The substrate 21 is made up of an insulating material with a large coefficient of thermal conductivity, for example, a ceramic material such as beryllium oxide, silicon carbide, aluminum nitride, aluminum oxide, which can facilitate the conduction of the heat energy of the light-emitting die 23 to the optical reflector, and then dissipate the heat energy to the outside of the light-emitting device immediately. The optical reflector 27 is made up of a metallic material, for example, copper, aluminum, or iron. Because the metallic material of the optical reflector 27 has a large reflectivity and a large coefficient of thermal conductivity, the incident light on the slope 271 can be reflected to achieve a light-guiding effect, and also the heat energy of the light-emitting die 23 can be dissipated to the outside of the light-emitting device instantly. More advantageously, the protecting material 25, which is filled in the gap above the top surface 211 can be also selected as a material with a large coefficient of thermal conductivity, and thereby improving the heat-dissipating efficiency of the light-emitting device.

Preferably, the optical reflector 27 is made up of a metallic material. Alternatively, the optical reflector 27 may be made up of a non-metallic material and plated with a metallic layer on its top surface to enhance its thermal conductivity.

By enabling the optical reflector to combine the heat-dissipating and light-guiding capabilities, the cost to be spent on the additional heat-dissipating structure can be saved, and the metal strips (121,123,125) that are used to provide a channel of electric power supply according to the prior art can be eliminated. In this way, the misgivings of unstable power supply or electrical leakage can be suppressed.

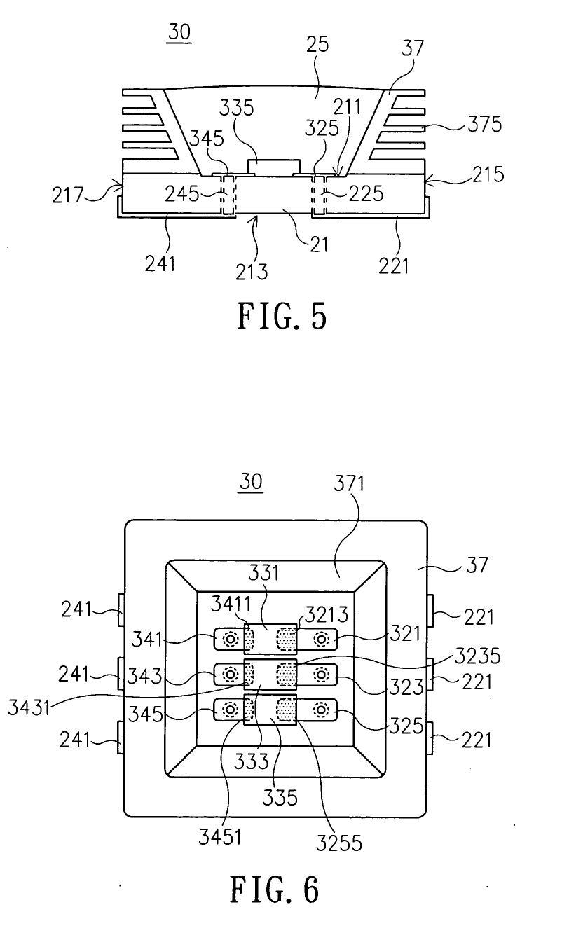

At last, referring to FIG. 5 and FIG. 6, a side view and a top-view of the light-emitting device according to another embodiment of the present invention are respectively illustrated. As shown, a light-emitting device includes a substrate 21, light-emitting dies 331,333,335 fixedly mounted on the top surface 211 of the substrate 21, and an optical reflector 37 fixedly mounted on the outer surface of the light-emitting dies 331,333,335.

The substrate 21 is provided with a plurality of power-supply circuits 321,341,323,343,325,345 which are respectively connected to a corresponding electrode 3311,3315,3331,3335,3351,3355 of the light-emitting dies 331,333,335, so as to provide an operating power for the light-emitting dies 331,333,335. The light-emitting dies 331,333,335 are respectively used for radiating red-colored, blue-colored, and green-colored lights, so that the light-emitting device 30 is capable of providing a white light source or a full-color light source.

In the present embodiment, more heat energy will be generated by a plurality of light-emitting dies 331,333,335. To cope with such deficiency, the optical reflector 37 can be so designed as to provide a plurality of heat fins 375 on its outer surface to increase the heat-dissipating area and improve the heat-dissipating efficiency.

Because the optical reflector 27,37 of the light-emitting device 20,30 according to the present invention is provided with a dual capability of light-guiding and heat-dissipating, the light-emitting device is not necessary to incorporate an additional heat-dissipating device, and the cost spent on the materials is reduced. Besides, the high operating temperature of the light-emitting device 20,30 can be receded by the optical reflector 27,37, and thus the temperatures of the power supply circuits 321,341,323,343,325,345 can be prevented from rising dramatically. In this manner, the safety in operation is upgraded, and the misgivings of electric leakage or the instability of the current of the light-emitting device 20,30 are suppressed. Certainly, with the timely dissipation of the heat energy generated by the light-emitting device 20,30, the light-emitting efficiency of the light-emitting device 20,30 is enhanced and the objective of saving energy is attained as well.

In summary, the present invention provides a light-emitting device, and more particularly a light-emitting device high heat-dissipating efficiency, in which an optical reflector combing the capabilities of light-guiding and heat-dissipating is mounted in the periphery of light-emitting die for increasing the heat-dissipating area of the light-emitting die and providing a light-guiding mechanism.

While the present invention has been described in terms of what are presently considered to be the most practical and preferred embodiments, it is to be understood that the present invention need not be restricted to the disclosed embodiment. On the contrary, it is intended to cover various modifications and similar arrangements included within the spirit and scope of the appended claims, which are to be accorded with the broadest interpretation so as to encompass all such modifications and similar structures. Therefore, the above description and illustration should not be taken as limiting the scope of the present invention which is defined by the appended claims.

1. A light-emitting device with high heat-dissipating efficiency, comprising:
a substrate having at least one pair of power-supply circuits;
at least one light-emitting die fixedly mounted on the top surface of the substrate, wherein the light-emitting die includes two electrodes which are electrically connected to a corresponding power-supply circuit, respectively; and
an optical reflector with heat-dissipating mounted on the top surface of the substrate and adjacently surrounds the light-emitting die for dissipating the heat energy generated by the light-emitting die to the outside of the light-emitting device.

2. The light-emitting device according to claim 1, wherein the optical reflector is formed by a metallic material.

3. The light-emitting device according to claim 1, wherein the optical reflector is formed by a non-metallic material.

4. The light-emitting device according to claim 3, wherein the surface of the optical reflector is coated with a metallic layer.

5. The light-emitting device according to claim 1, wherein the optical reflector is provided with a plurality of heat fins on an outer surface thereof.

6. The light-emitting device according to claim 1, wherein the light-emitting die is fixedly mounted on the substrate by flip-chip mounting.

7. The light-emitting device according to claim 1, wherein the optical reflector is padded with gel.

8. The light-emitting device according to claim 1, wherein the substrate is a ceramic substrate.

9. The light-emitting device according to claim 1, wherein the substrate is formed by one or an alloy of a group of materials consisting of beryllium oxide, silicon carbide, aluminum nitride, and aluminum oxide.

10. The light-emitting device according to claim 1, wherein the substrate is provided with at least one perforation penetratingly mounted on the substrate for allowing the power-supply circuits to pass through and extending from the top surface of the substrate to the bottom surface of the substrate.

11. The light-emitting device according to claim 1, wherein the power-supply circuits are configured to extend from the bottom surface of the substrate to a side surface of the substrate.
